(19) United States
(12) Patent Application Publication
(10) Pub. No.: US 2020/0335154 A1
(43) Pub. Date: Oct. 22, 2020

(54) MEMORY DEVICE

(71) Applicant: SK hynix Inc., Gyeonggi-do (KR)

(72) Inventors: Hee-Jin BYUN, Gyeonggi-do (KR); Hyung-Sik WON, Chungcheongbuk-do (KR)

(21) Appl. No.: 16/692,687

(22) Filed: Nov. 22, 2019

(30) Foreign Application Priority Data
Apr. 22, 2019 (KR) 10-2019-0046911

(51) Int. Cl. G11C 11/406; G11C 15/06; G11C 17/16

(52) U.S. Cl. CPC G11C 11/40626; G11C 11/40622; G11C 17/16; G11C 15/06; G11C 11/40618

(57) ABSTRACT

A memory device includes a memory region, and a setting circuit suitable for changing setting information based on a temperature information signal so that the memory region operates according to a first condition at pseudo cryogenic temperature, and operates according to a second condition at room temperature.

### CROSS-REFERENCE TO RELATED APPLICATION

This application claims priority under 35 U.S.C. § 119 to Korean Patent Application No. 10-2019-0046911, filed on Apr. 22, 2019, the disclosure of which is incorporated herein by reference in its entirety.

### BACKGROUND

### 1. Field

Various embodiments relate to a semiconductor design technique, and more particularly, to a memory device that operates at cryogenic temperature, and an operating method thereof.

### 2. Description of the Related Art

A memory device operating at cryogenic temperature consumes much less power than a memory device operating at room temperature. For example, a memory cell in a dynamic random access memory (DRAM) operating at cryogenic temperature has a longer data retention time than that of a DRAM operating at room temperature. Therefore, the DRAM operating at cryogenic temperature seldom performs a refresh operation or maximizes a refresh period, thereby reducing power consumption.

### SUMMARY

Various embodiments are directed to a memory device capable of adaptively operating at a pseudo cryogenic temperature and room temperature, and an operating method of the memory device.

In accordance with an embodiment, a memory device includes: a memory region; and a setting circuit suitable for changing setting information based on a temperature information signal so that the memory region operates according to a first condition at pseudo cryogenic temperature, and operates according to a second condition at room temperature.

The pseudo cryogenic temperature may include 77K±7K.

The setting information may include information related to a refresh operation.

The memory device may further include a setting control circuit suitable for generating the temperature information signal.

The setting control circuit may include any one of a mode register set and a fuse circuit.

The setting control circuit may include a temperature sensor.

In accordance with an embodiment, a memory device includes: a setting circuit suitable for generating first setting information as memory setting information at pseudo cryogenic temperature, and generating second setting information as the memory setting information at room temperature, based on a temperature information signal; a refresh control circuit suitable for generating one or more refresh control signals corresponding to any one of the first and second setting information based on the memory setting information and a refresh signal; and a memory region suitable for performing a refresh operation according to a first condition corresponding to the first setting information or performing a refresh operation according to a second condition corresponding to the second setting information, based on the refresh control signals and an address signal.

The pseudo cryogenic temperature may include 77K±7K.

The memory setting information may include time information indicating a difference between an active time point and a precharge time point, which corresponds to a refresh period.

The memory region may include a plurality of bank groups, the refresh control circuit may generate a plurality of refresh control signals corresponding to the plurality of bank groups, and the memory setting information may include delay time information indicating is differences between the plurality of refresh control signals.

The setting circuit may include: a first storage circuit suitable for storing the first setting information; a second storage circuit suitable for storing the second setting information; and a setting selection circuit suitable for outputting any one of the first and second setting information as the memory setting information based on the temperature information signal.

The memory device may further include a setting control circuit suitable for generating the temperature information signal.

The setting control circuit may include any one of a mode register set and a fuse circuit.

The setting control circuit may include a temperature sensor.

In accordance with an embodiment, an operating method of a memory device: determining a temperature of the memory device; generating first setting information as memory setting information when the temperature of the memory device is a pseudo cryogenic temperature; generating one or more refresh control signals based on the memory setting information; and performing a refresh operation according to a first condition corresponding to the pseudo cryogenic temperature, based on the refresh control signals.

The pseudo cryogenic temperature may include 77K±7K.

The memory setting information may include time information indicating a difference between an active time point and a precharge time point, which corresponds to a refresh period.

The memory setting information may include delay time information indicating differences between a plurality of bank groups when the bank groups are sequentially refreshed.

The operating method may further include: generating second setting information as the memory setting information when the temperature of the memory device is room temperature; generating the refresh control signals based on the memory setting information; and performing the refresh operation according to a second condition corresponding to the room temperature, based on the refresh control signals.

The determining of the temperature of the memory device may be performed based on a temperature information signal stored in the memory device in advance or based on a temperature information signal generated by measuring the temperature of the memory device in real time.

In accordance with an embodiment, a memory device includes: a memory region including a plurality of banks, which operates at room temperature or pseudo cryogenic temperature; a setting circuit including a storage, which stores first refresh related setting information for the room temperature and second refresh related setting information for the pseudo cryogenic temperature, suitable for selectively outputting one of the first refresh related setting information and the second refresh related setting information as memory setting information in response to a temperature information signal; and a refresh control circuit suitable for generating a selected refresh control signal of a first refresh control signal for the room temperature and a second refresh signal for the pseudo cryogenic temperature, based on the memory setting information, and outputting the selected refresh control signal to the memory region.

### BRIEF DESCRIPTION OF THE DRAWINGS

FIG. 1 is a block diagram illustrating a memory device in accordance with an embodiment.

FIG. 2 is a block diagram illustrating a setting circuit shown in FIG. 1.

FIG. 3 is a block diagram illustrating a setting selection circuit shown in FIG. 2.

FIG. 4 is a timing diagram illustrating an operation of the memory device shown in FIG. 1.

### DETAILED DESCRIPTION

Various embodiments are described below in more detail with reference to the accompanying drawings. These embodiments are provided so that this disclosure is thorough and complete, and fully conveys the scope of the present disclosure to those skilled in the art.

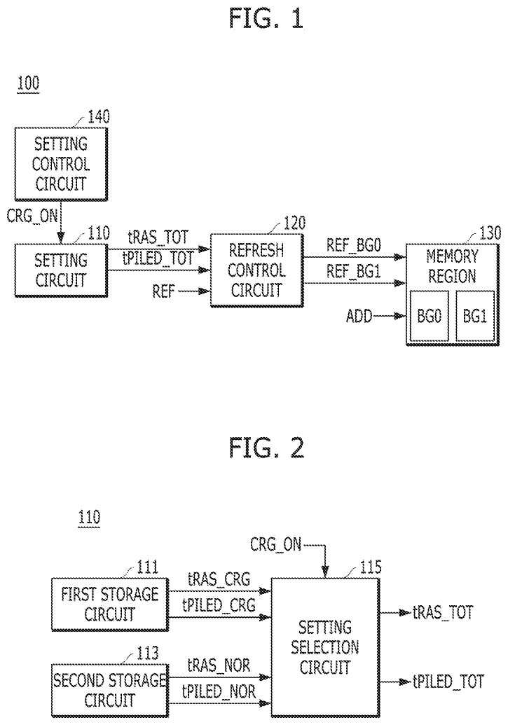

FIG. 1 is a block diagram illustrating a memory device 100 in accordance with an embodiment.

Referring to FIG. 1, the memory device 100 may include a setting circuit 110, a refresh control circuit 120, a memory region 130 and a setting control circuit 140.

In some embodiments, the memory region 130 includes first and second bank groups BG0 and BG1, and first and second refresh control signals REF_BG0 and REF_BG1 are generated from the refresh control circuit 120.

The setting circuit 110 may change memory setting information tRAS_TOT and tPILED_TOT based on a temperature information signal CRG_ON so that the memory region 130 operates according to a first condition at pseudo cryogenic temperature and operates according to a second condition at room temperature. In other words, the setting circuit 110 may generate first setting information tRAS_CRG and tPILED_CRG as the memory setting information tRAS_TOT and tPILED_TOT at the pseudo cryogenic temperature, respectively, and generate second setting information tRAS_NOR and tPILED_NOR as the memory setting information tRAS_TOT and tPILED_TOT at room temperature, respectively, based on the temperature information signal CRG_ON.

The pseudo cryogenic temperature may include 77K±7K, and have a temperature range in which a memory device implemented with a complementary metal-oxide-semiconductor (CMOS) device can operate. The room temperature may refer to general room temperature, that is, 300K, or a temperature that is higher than the pseudo cryogenic temperature.

The refresh control circuit 120 may generate the first and second refresh control signals REF_BG0 and REF_BG1 which correspond to the first setting information tRAS_CRG and tPILED_CRG or the second setting information tRAS_NOR and tPILED_NOR, based on the memory setting information tRAS_TOT and tPILED_TOT and a refresh signal REF. The refresh signal REF may be activated in a refresh mode. For example, the refresh control circuit 120 may generate the first and second refresh control signals REF_BG0 and REF_BG1 corresponding to the first setting information tRAS_CRG and tPILED_CRG at the pseudo cryogenic temperature. Further, the refresh control circuit 120 may generate the first and second refresh control signals REF_BG0 and REF_BG1 corresponding to the second setting information tRAS_NOR and tPILED_NOR at the room temperature.

The memory region 130 may perform a refresh operation according to the first condition corresponding to the first setting information tRAS_CRG and tPILED_CRG or perform the refresh operation according to the second condition corresponding to the second setting information tRAS_NOR and tPILED_NOR, based on the first and second refresh control signals REF_BG0 and REF_BG1 and an address signal ADD. The memory region 130 may include the first and second bank groups BG0 and BG1. Each of the first and second bank groups BG0 and BG1 may include a plurality of banks. The first bank group BG0 may perform the refresh operation according to the first condition at the pseudo cryogenic temperature, based on the first refresh control signal REF_BG0 and the address signal ADD. Further, the first bank group BG0 may perform the refresh operation according to the second condition at the room temperature, based on the first refresh control signal REF_BG0 and the address signal ADD. The second bank group BG1 may perform the refresh operation according to the first condition at the pseudo cryogenic temperature, and perform the refresh operation according to the second condition at the room temperature, based on the second refresh control signal REF_BG1 and the address signal ADD. The address signal ADD may include a bank group address signal, a bank address signal, a column address signal and a row address signal.

The memory region 130 may typically include the CMOS device, and operate stably at the pseudo cryogenic temperature. In addition, since the memory region 130 rarely requires a refresh operation at the pseudo cryogenic temperature, the memory region 130 is more advantageous in terms of power when operating at the pseudo cryogenic temperature than when operating at the room temperature.

The setting control circuit 140 may generate the temperature information signal CRG_ON corresponding to an internal temperature of the memory device 100. In some embodiments, the setting control circuit 140 may be designed to store the temperature information signal CRG_ON corresponding to an internal temperature of the memory device 100 in advance. For example, the setting control circuit 140 may be designed to include any one of a mode register set and a fuse circuit. In some embodiments, the setting control circuit 140 may be designed to generate the temperature information signal CRG_ON by measuring the internal temperature of the memory device 100 in real time, that is, directly. For example, the setting control circuit 140 may include a temperature sensor.

FIG. 2 is a block diagram illustrating the setting circuit 110 shown in FIG. 1.

Referring to FIG. 2, the setting circuit 110 may include a first storage circuit 111, a second storage circuit 113 and a setting selection circuit 115.

The first storage circuit 111 may store the first setting information tRAS_CRG and tPILED_CRG. The first setting information tRAS_CRG and tPILED_CRG may include information related to a refresh operation. For example, the first setting information tRAS_CRG and tPILED_CRG may include time information tRAS_CRG and delay time information tPILED_CRG. The time information tRAS_CRG (hereinafter referred to as “first time information”) may represent information indicating a difference between an active time point and a precharge time point, which corresponds to a refresh period. The delay time information tPILED_CRG (hereinafter referred to as “first delay time information”) may represent information indicating a difference between the first refresh control signal REF_BG0 and the second refresh control signal REF_BG1, at the pseudo cryogenic temperature.

The second storage circuit 113 may store the second setting information tRAS_NOR and tPILED_NOR. The second setting information tRAS_NOR and tPILED_NOR may include information related to a refresh operation. For example, the second setting information tRAS_NOR and tPILED_NOR may include time information tRAS_NOR and delay time information tPILED_NOR. The time information tRAS_NOR (hereinafter referred to as “second time information”) may represent information indicating a difference between an active time point and a precharge time point, which corresponds to a refresh period. The delay time information tPILED_NOR (hereinafter referred to as “second delay time information”) may represent information indicating a difference between the first refresh control signal REF_BG0 and the second refresh control signal REF_BG1, at the room temperature.

The setting selection circuit 115 may output the first setting information tRAS_CRG and tPILED_CRG as the memory setting information tRAS_TOT and tPILED_TOT or output the second setting information tRAS_NOR and tPILED_NOR as the memory setting information tRAS_TOT and tPILED_TOT, based on the temperature information signal CRG_ON. For example, the setting selection circuit 115 may output the first setting information tRAS_CRG and tPILED_CRG as the memory setting information tRAS_TOT and tPILED_TOT at the pseudo cryogenic temperature. Further, the setting selection circuit 115 may output the second setting information tRAS_NOR and tPILED_NOR as the memory setting information tRAS_TOT and tPILED_TOT at the room temperature.

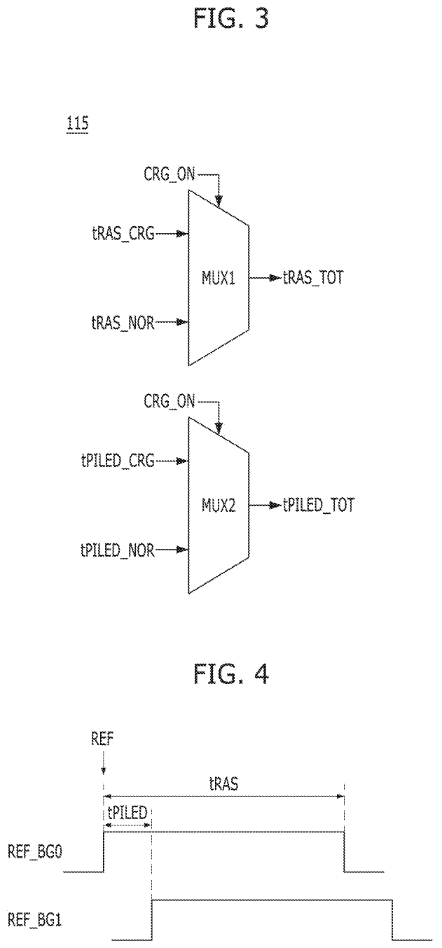

FIG. 3 is a block diagram illustrating the setting selection circuit 115 shown in FIG. 2.

Referring to FIG. 3, the setting selection circuit 115 may include a first multiplexer MUX1 and a second multiplexer MUX2.

The first multiplexer MUX1 may output any one of the first time information tRAS_CRG and the second time information tRAS_NOR as third time information tRAS_TOT of the memory setting information tRAS_TOT and tPILED_TOT based on the temperature information signal CRG_ON. For example, the first multiplexer MUX1 may output the first time information tRAS_CRG as the third time information tRAS_TOT at the pseudo cryogenic temperature. Further, the first multiplexer MUX1 may output the second time information tRAS_NOR as the third time information tRAS_TOT at the room temperature.

The second multiplexer MUX2 may output any one of the first delay time information tPILED_CRG and the second delay time information tPILED_NOR as third delay time information tPILED_TOT of the memory setting information tRAS_TOT and tPILED_TOT based on the temperature information signal CRG_ON. For example, the second multiplexer MUX2 may output the first delay time information tPILED_CRG as the third delay time information tPILED_TOT at the pseudo cryogenic temperature. Further, the second multiplexer is MUX2 may output the second delay time information tPILED_NOR as the third delay time information tPILED_TOT at the room temperature.

Hereinafter, an operation of the memory device 100 having the above-described configuration in accordance with the present embodiment will be described with reference to FIG. 4.

FIG. 4 is a timing diagram illustrating an operation of the memory device 100 shown in FIG. 1.

Referring to FIG. 4, the first refresh control signal REF_BG0 and the second refresh control signal REF_BG1 may be sequentially generated. At this time, the first and second refresh control signals REF_BG0 and REF_BG1 may be generated in consideration of a refresh period tRAS and a delay time tPILED depending on temperatures, that is, the cryogenic temperature and the room temperature. The refresh period tRAS may correspond to an active width of each of the first and second refresh control signals REF_BG0 and REF_BG1. The delay time tPILED may correspond to a difference between active time points of the first and second refresh control signals REF_BG0 and REF_BG1.

An operating method of the memory device 100 is as follows.

The memory device 100 may determine a temperature thereof. For example, the memory device 100 may determine the temperature thereof based on the temperature information signal CRG_ON which has been stored therein in advance. For another example, the memory device 100 may determine the temperature thereof based on the temperature information signal CRG_ON which is generated by measuring the temperature therein in real time.

When the temperature of the memory device 100 is the pseudo cryogenic temperature, the memory device 100 may generate the first setting information tRAS_CRG and tPILED_CRG as the memory setting information tRAS_TOT and tPILED_TOT. Accordingly, the memory device 100 may generate the first and second refresh control signals REF_BG0 and REF_BG1 based on the memory setting information tRAS_TOT and tPILED_TOT, thereby controlling the memory region 130 to perform the refresh operation according to the first condition corresponding to the pseudo cryogenic temperature.

When the temperature of the memory device 100 is the room temperature, the memory device 100 may generate the second setting information tRAS_NOR and tPILED_NOR as the memory setting information tRAS_TOT and tPILED_TOT. Accordingly, the memory device 100 may generate the first and second refresh control signals REF_BG0 and REF_BG1 based on the memory setting information tRAS_TOT and tPILED_TOT, thereby controlling the memory region 130 to perform the refresh operation according to the second condition corresponding to the room temperature.

As is apparent from the above descriptions, the memory device in accordance with the present embodiment may adaptively operate at pseudo cryogenic temperature and room temperature.

According to the present embodiment, since the memory is device may adaptively operate at a pseudo cryogenic temperature and room temperature, there is no need to separately design the memory device according to the temperatures, thereby reducing the manufacturing cost.

While the present invention has been illustrated and described with respect to specific embodiments, the disclosed embodiments are not intended to be restrictive. Further, it is noted that the present invention may be achieved in various ways through substitution, change, and modification, as those skilled in the art will recognize in light of the present disclosure, without departing from the spirit and/or scope of the present disclosure. The present invention is intended to embrace all such substitutions, changes and modifications that fall within the scope of the following claims.

For example, although it is described in the present embodiment that refresh related information is changed according to a pseudo cryogenic temperature and room temperature, the embodiment is not necessarily limited thereto, and may be applied to changing bias voltage related information according to the pseudo cryogenic temperature and the room temperature.

What is claimed is:

1. A memory device comprising:
a memory region; and
a setting circuit suitable for changing setting information based on a temperature information signal so that the memory region operates according to a first condition at pseudo cryogenic temperature, and operates according to a second condition at room temperature.

2. The memory device of claim 1, wherein the pseudo cryogenic temperature includes 77K±7K.

3. The memory device of claim 1, wherein the setting information includes information related to a refresh operation.

4. The memory device of claim 1, further comprising a setting control circuit suitable for generating the temperature information signal.

5. The memory device of claim 4, wherein the setting control circuit includes any one of a mode register set and a fuse circuit.

6. The memory device of claim 4, wherein the setting control circuit includes a temperature sensor.

7. A memory device comprising:
a setting circuit suitable for generating first setting information as memory setting information at pseudo cryogenic temperature, and generating second setting information as the memory setting information at room temperature, based on a temperature information signal;
a refresh control circuit suitable for generating one or more refresh control signals corresponding to any one of the first and second setting information based on the memory setting information and a refresh signal; and
a memory region suitable for performing a refresh operation according to a first condition corresponding to the first setting information or performing a refresh operation according to a second condition corresponding to the second setting information, based on the refresh control signals and an address signal.

8. The memory device of claim 7, wherein the pseudo cryogenic temperature includes 77K±7K.

9. The memory device of claim 7, wherein the memory setting information includes time information indicating a difference between an active time point and a precharge time point, which corresponds to a refresh period.

10. The memory device of claim 7, wherein the memory region includes a plurality of bank groups,
wherein the refresh control circuit generates a plurality of refresh control signals corresponding to the plurality of bank groups, and
wherein the memory setting information includes delay time information indicating differences between the plurality of refresh control signals.

11. The memory device of claim 7, wherein the setting circuit includes:
a first storage circuit suitable for storing the first setting information;
a second storage circuit suitable for storing the second setting information, and
a setting selection circuit suitable for outputting any one of the first and second setting information as the memory setting information based on the temperature information signal.

12. The memory device of claim 7, further comprising a setting control circuit suitable for generating the temperature information signal.

13. The memory device of claim 12, wherein the setting control circuit includes any one of a mode register set and a fuse circuit.

14. The memory device of claim 12, wherein the setting control circuit includes a temperature sensor.

15. An operating method of a memory device comprising:
determining a temperature of the memory device;
generating first setting information as memory setting information when the temperature of the memory device is a pseudo cryogenic temperature;
generating one or more refresh control signals based on the memory setting information; and
performing a refresh operation according to a first condition corresponding to the pseudo cryogenic temperature, based on the refresh control signals.

16. The operating method of claim 15, wherein the pseudo cryogenic temperature includes 77K±7K.

17. The operating method of claim 15, wherein the memory setting information includes time information indicating a difference between an active time point and a precharge time point, which corresponds to a refresh period.

18. The operating method of claim 15, wherein the memory setting information includes delay time information indicating differences between a plurality of bank groups when the bank groups are sequentially refreshed.

19. The operating method of claim 15, further comprising:
generating second setting information as the memory setting information when the temperature of the memory device is room temperature;
generating the refresh control signals based on the memory setting information; and
performing the refresh operation according to a second condition corresponding to the room temperature, based on the refresh control signals.

20. The operating method of claim 15, wherein the determining of the temperature of the memory device is performed based on a temperature information signal stored in the memory device in advance or based on a temperature information signal generated by measuring the temperature of the memory device in real time.
